(19) United States
(12) Patent Application Publication
(10) Pub. No.: US 2026/0198386 A1
(43) Pub. Date: Jul. 9, 2026

(54) SEMICONDUCTOR DEVICE AND ELECTRONIC SYSTEM INCLUDING THE SAME

(71) Applicant: Samsung Electronics Co., Ltd., Suwon-si (KR)

(72) Inventors: Yeon Wook JUNG, Suwon-si (KR); Gyo Soo CHOO, Suwon-si (KR)

(21) Appl. No.: 19/442,221

(22) Filed: Jan. 7, 2026

(30) Foreign Application Priority Data
Jan. 7, 2025 (KR) 10-2025-0002324

(51) Int. Cl. H10W 90/20; H10B 43/10; H10B 43/27; H10B 43/35; H10B 80/00; H10D 80/30; H10W 72/59; H10W 72/90; H10W 90/00

(52) U.S. Cl. CPC H10W 90/297; H10B 43/10; H10B 43/27; H10B 43/35; H10B 80/00; H10D 80/30; H10W 72/59; H10W 72/926; H10W 90/752; H10W 90/792

(57) ABSTRACT

A semiconductor device includes a cell structure including a first region including memory cells and a second region located at an edge of the first region, a peripheral circuit structure including a peripheral circuit electrically connected to the cell structure, a through via extending in a vertical direction within the second region of the cell structure, a first pad structure connected to the through via, in the second region, and a second pad structure on the cell structure, in the first region. The first pad structure includes a via pad in contact with the through via and a heat conductive pad positioned within an opening, above the via pad.

### CROSS-REFERENCE TO RELATED APPLICATION

This application claims priority from Korean Patent Application No. 10-2025-0002324 filed on Jan. 7, 2025 in the Korean Intellectual Property Office, and all the benefits accruing therefrom under 35 U.S.C. 119, the contents of which in its entirety are herein incorporated by reference.

### BACKGROUND

### 1. Field

The present disclosure relates to a semiconductor device and an electronic system including the same.

### 2. Description of the Related Art

With the rapid development of the electronics industry and increasing user demands, electronic devices are becoming increasingly smaller, more multifunctional, and higher in capacity. As a result, semiconductor devices including multiple semiconductor chips are required. Particularly, for recent semiconductor devices with a large number of signal input/output lines, high capacity, and fast operation speeds, the need for effectively dissipating heat has increased.

### SUMMARY

An objective of the present disclosure is to provide a semiconductor device with improved heat dissipation characteristics.

Another objective of the present disclosure is to provide an electronic system including a semiconductor device with improved heat dissipation characteristics.

The objectives of the present disclosure are not limited to those mentioned above, and other objectives not explicitly stated will be clearly understood by those skilled in the art based on the following description.

According to some embodiments, a semiconductor device comprises a cell structure including a first region comprising memory cells and a second region located at an edge of the first region, a peripheral circuit structure including a peripheral circuit electrically connected to the cell structure, a through via extending in a vertical direction within the second region of the cell structure, a first pad structure connected to the through via, in the second region, and a second pad structure on the cell structure, in the first region. The first pad structure includes a via pad in contact with the through via and a heat conductive pad positioned within an opening, above the via pad.

According to some embodiments, a semiconductor device comprises a cell structure including memory cells, a peripheral circuit structure including a peripheral circuit electrically connected to the cell structure, a through via extending in a vertical direction within the cell structure and positioned on the peripheral circuit structure, a pad structure connected to, and positioned on, the through via, and a bonding wire connected to the pad structure. The pad structure includes a via pad and a heat conductive pad positioned within an opening. The heat conductive pad is positioned above the via pad. The via pad does not contact the bonding wire, while the heat conductive pad is connected to, and contacts, the bonding wire.

According to some embodiments, a semiconductor device comprises a cell structure including memory cells, a peripheral circuit structure including a first peripheral circuit and a second peripheral circuit, each electrically connected to the cell structure, a first pad structure positioned adjacent to the first peripheral circuit, and a second pad structure positioned adjacent to the second peripheral circuit. The first pad structure includes a first via pad and a first heat conductive pad positioned within a first opening. The first heat conductive pad is positioned above the first via pad. A size of the first pad structure is larger than a size of the second pad structure.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a schematic diagram illustrating an electronic system including a semiconductor device according to some embodiments of the present disclosure;

FIG. 2 is a perspective view schematically illustrating an electronic system including a semiconductor device according to some embodiments of the present disclosure;

FIGS. 3 and 4 are cross-sectional views schematically illustrating semiconductor packages according to some embodiments of the present disclosure;

FIG. 5 is a plan view of a semiconductor device according to some embodiments of the present disclosure;

FIG. 6 is a cross-sectional view, taken along line A-A′ of FIG. 5, of the semiconductor device according to some embodiments of the present disclosure;

FIGS. 7 and 8 are exemplary enlarged cross-sectional views illustrating region R of FIG. 6;

FIGS. 9 through 19 are cross-sectional views of the semiconductor device according to some embodiments of the present disclosure, and correspond to FIG. 6;

FIGS. 20 through 24 are plan views of the semiconductor device according to some embodiments of the present disclosure, illustrating the semiconductor package in FIG. 3 or 4 as viewed from above.

FIG. 25 is a flowchart illustrating a method of forming the semiconductor device according to some embodiments of the present disclosure.

### DETAILED DESCRIPTION

Embodiments of the present disclosure will hereinafter be described with reference to the accompanying drawings.

Throughout the specification, when a component is described as “including” a particular element or group of elements, it is to be understood that the component is formed of only the element or the group of elements, or the element or group of elements may be combined with additional elements to form the component, unless the context clearly and/or explicitly describes the contrary.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

As used herein, components described as being “electrically connected” are configured such that an electrical signal can be transferred from one component to the other (although such electrical signal may be attenuated in strength as it is transferred and may be selectively transferred).

Spatially relative terms, such as “beneath,” “below,” “lower,” “above,” “upper,” “top,” “bottom,” “front,” “rear,” and the like, may be used herein for ease of description to describe positional relationships, such as illustrated in the figures, for example. It will be understood that the spatially relative terms encompass different orientations of the device in addition to the orientation depicted in the figures.

Various pads of a device described herein may be conductive terminals connected to internal wiring of the device, and may transmit signals and/or supply voltages between an internal wiring and/or internal circuit of the device and an external source. For example, chip pads of a semiconductor chip may electrically connect to and transmit supply voltages and/or signals between an integrated circuit of the semiconductor chip and a device to which the semiconductor chip is connected. The various pads may be provided on or near an external surface of the device and may have a planar surface having dimensions greater than wiring (e.g., X-Y horizontal dimensions of a pad are both greater than the width of an internal writing to which it is connected) to promote an electrical connection to a further terminal, such as a bump or solder ball, and/or an external wiring.

Components described as thermally connected or in thermal communication are arranged such that heat will follow a path between the components to allow the heat to transfer from the first component to the second component. Simply because two components are part of the same device or package does not make them thermally connected. In general, components which are heat-conductive and directly connected to other heat-conductive or heat-generating components (or connected to those components through intermediate heat-conductive components or in such close proximity as to permit a substantial transfer of heat) will be described as thermally connected to those components, or in thermal communication with those components. On the contrary, two components with heat-insulative materials therebetween, which materials significantly prevent heat transfer between the two components, or only allow for incidental heat transfer, are not described as thermally connected or in thermal communication with each other. The terms “heat conductive” or “thermally conductive” do not apply to a particular material simply because it provides incidental heat conduction, but are intended to refer to materials that are typically known as good heat conductors or known to have utility for transferring heat, or components having similar heat conducting properties as those materials.

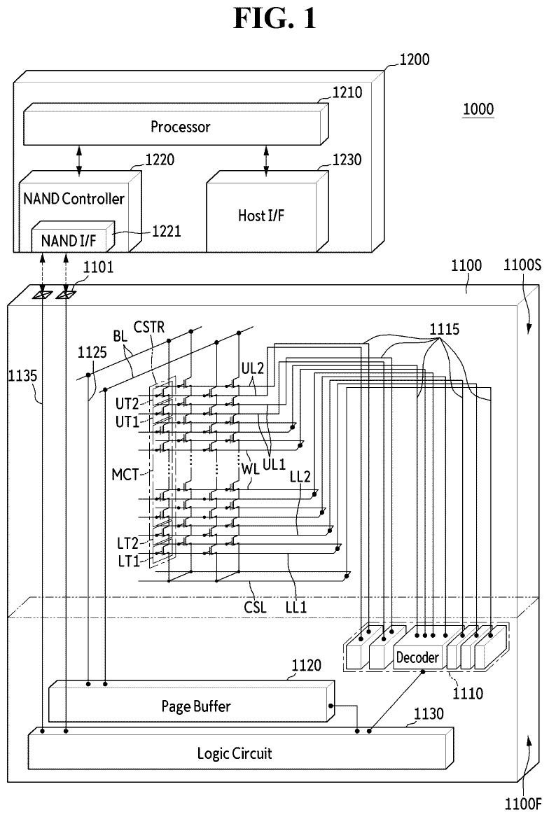

FIG. 1 is a schematic diagram illustrating an electronic system including a semiconductor device according to some embodiments of the present disclosure.

Referring to FIG. 1, an electronic system 1000 may include a semiconductor device 1100 and a controller 1200 electrically connected to the semiconductor device 1100. The electronic system 1000 may be a storage device including at least one semiconductor device 1100 or an electronic device including the storage device. For example, the electronic system 1000 may be a solid-state drive (SSD) device, a universal serial bus (USB) device, a computing system, a medical device, or a communication device that includes at least one semiconductor device 1100.

The semiconductor device 1100 may be a non-volatile memory device, such as, for example, a NAND flash memory device.

The semiconductor device 1100 may include a first structure 1100F and a second structure 1100S on the first structure 1100F. In some embodiments, the first structure 1100F may be positioned adjacent to the second structure 1100S.

The first structure 1100F may be a peripheral circuit structure including a decoder circuit 1110, a page buffer 1120, and a logic circuit 1130. The second structure 1100S may be a memory cell structure including bitlines BL, a common source line CSL, wordlines WL, first upper gate lines UL1, second upper gate lines UL2, first lower gate lines LL1, second lower gate lines LL2, and memory cell strings CSTR between the bitlines BL and the common source line CSL.

In the second structure 1100S, the memory cell strings CSTR may each include lower transistors LT1 and LT2 adjacent to the common source line CSL, upper transistors UT1 and UT2 adjacent to the bitlines BL, and a plurality of memory cell transistors MCT between the lower transistors LT1 and LT2 and the upper transistors UT1 and UT2. The numbers of lower transistors (LT1 and LT2) and upper transistors (UT1 and UT2) may vary.

In some embodiments, the upper transistors (UT1 and UT2) may include string selection transistors, and the lower transistors (LT1 and LT2) may include ground selection transistors. The first lower gate lines LL1 and the second lower gate lines LL2 may serve as gate electrodes of the lower transistors LT1 and gate electrodes of the lower transistors LT2, respectively. The wordlines WL may serve as gate electrodes of the memory cell transistors MCT, and the first upper gate lines UL1 and the second upper gate lines UL2 may serve as gate electrodes of the upper transistors UT1 and gate electrodes of the upper transistors UT2, respectively.

In some embodiments, the lower transistors LT1 and the lower transistors LT2 may include a serially connected lower erase control transistor LT1 and a ground selection transistor LT2. The upper transistors (UT1 and UT2) may include serially connected string selection transistors UT1 and upper erase control transistors UT2. At least one of the lower erase control transistors LT1 and upper erase control transistors UT1 may be used in an erase operation to delete data stored in the memory cell transistors MCT using a gate-induced drain leakage (GIDL) phenomenon.

The common source line CSL, the first lower gate lines LL1, the second lower gate lines LL2, the wordlines WL, and the first upper gate lines UL1, and the second upper gate lines UL2 may be electrically connected to the decoder circuit 1110 through first connection wiring 1115 extending from the first structure 1100F to the second structure 1100S. The bitlines BL may be electrically connected to the page buffer 1120 through second connection wiring 1125 extending from the first structure 1100F to the second structure 1100S.

In the first structure 1100F, the decoder circuit 1110 and the page buffer 1120 may perform a control operation for at least one selected memory cell transistor MCT. The decoder circuit 1110 and the page buffer 1120 may be controlled by the logic circuit 1130. The semiconductor device 1100 may communicate with the controller 1200 through input/output pads 1101 electrically connected to the logic circuit 1130. The input/output pads 1101 may be electrically connected to the logic circuit 1130 through input/output connection wiring 1135 extending from the first structure 1100F to the second structure 1100S.

Although not illustrated, the first structure 1100F may receive addresses, commands, and control signals from outside the semiconductor device 1100 and may exchange data with external devices. Additionally, although not illustrated, the first structure 1100F may include various sub-circuits such as an input/output circuit, a voltage generation circuit for generating various voltages required for the operation of the semiconductor device 1100, and an error correction circuit for correcting errors in data read from the second structure 1100S.

For example, the voltage generation circuit may generate a program voltage, a read voltage, a pass voltage, and a verification voltage required for the operation of the memory cell strings CSTR. Here, the program voltage may be relatively high (e.g., 20V to 40V) compared to the read, pass, and verification voltages.

In some embodiments, the first structure 1100F may include high-voltage transistors and low-voltage transistors. The decoder circuit 1110 may include pass transistors connected to the wordlines WL of the memory cell strings CSTR. The pass transistors may include high-voltage transistors capable of withstanding a high voltage, such as the program voltage applied to the wordlines WL during a program operation. The page buffer 1120 may also include high-voltage transistors capable of withstanding a high voltage.

The logic circuit 1130 may be connected to the row decoder 1110, the input/output circuit, and the voltage generation circuit. The logic circuit 1130 may control the overall operation of the semiconductor device 1100. The logic circuit 1130 may generate various internal control signals used within the semiconductor device 1100 in response to a control signal. For example, the logic circuit 1130 may adjust voltage levels provided to the wordlines WL and the bitlines BL during a memory operation such as a program or erase operation.

The decoder circuit 1110 may select at least one of a plurality of memory cell blocks in response to an address, and may select at least one of the wordlines WL, at least one of the first upper gate lines UL1 or second upper gate lines UL2, and at least one of the first lower gate lines LL1 or second lower gate lines LL2 for the selected memory cell block. Additionally, the decoder circuit 1110 may deliver the voltage required for performing a memory operation to the wordline WL of the selected memory cell block.

The page buffer 1120 may be connected to the second structure 1100S through the bitlines BL. The page buffer 1120 may operate as a write driver or a sense amplifier. Specifically, during a program operation, the page buffer 1120 may operate as a write driver to apply a voltage corresponding to data to be stored in the second structure 1100S to the bitlines BL. During a read operation, the page buffer 1120 may operate as a sense amplifier to detect data stored in the second structure 1100S.

The controller 1200 may include a processor 1210, a NAND controller 1220, and a host interface 1230. In some embodiments, the electronic system 1000 may include a plurality of semiconductor devices 1100, in which case, the controller 1200 may control the plurality of semiconductor devices 1100.

The processor 1210 may control the overall operation of the electronic system 1000, including the controller 1200. The processor 1210 may operate according to a specific firmware and may control the NAND controller 1220 to access the semiconductor device 1100. The NAND controller 1220 may include a NAND interface 1221 for handling communication with the semiconductor device 1100. Through the NAND interface 1221, a control command for controlling the semiconductor device 1100, data to be written to the memory cell transistors MCT of the semiconductor device 1100, and data to be read from the memory cell transistors MCT of the semiconductor device 1100 may be transmitted. The host interface 1230 may provide a communication function between the electronic system 1000 and an external host. Upon receiving a control command from the external host through the host interface 1230, the processor 1210 may control the semiconductor device 1100 in response to the control command.

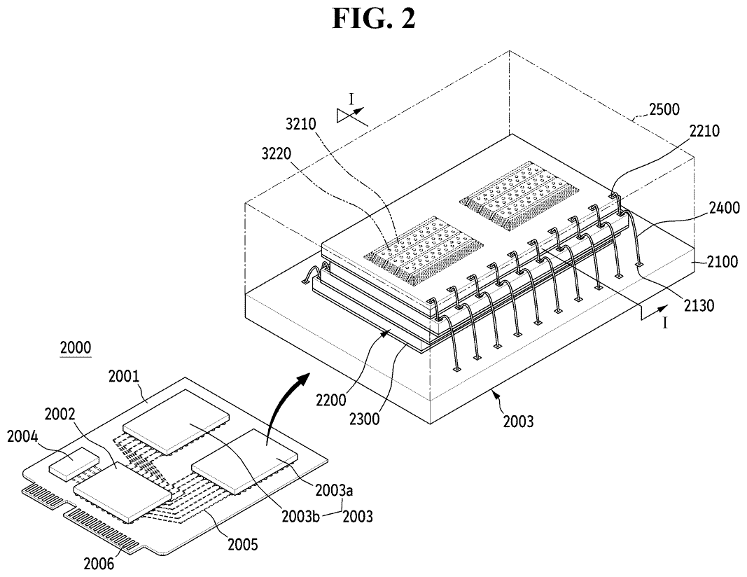

FIG. 2 is a perspective view schematically illustrating an electronic system including a semiconductor device according to some embodiments of the present disclosure.

Referring to FIG. 2, an electronic system 2000 may include a main board 2001, a controller 2002 mounted on the main board 2001, at least one semiconductor package 2003, and a DRAM 2004. The semiconductor package 2003 and the DRAM 2004 may be interconnected with the controller 2002 via wiring patterns 2005 formed on the main board 2001.

The main board 2001 may include connectors 2006 having a plurality of pins connected to an external host. The number and arrangement of pins in the connectors 2006 may vary depending on the communication interface between the electronic system 2000 and the external host. In some exemplary embodiments, the electronic system 2000 may communicate with the external host via one of the following interfaces: Universal Serial Bus (USB), Peripheral Component Interconnect Express (PCI-Express), Serial Advanced Technology Attachment (SATA), or Universal Flash Storage (UFS) M-Phy. In some exemplary embodiments, the electronic system 2000 may operate using power supplied from the external host via the connectors 2006. The electronic system 2000 may further include a power management integrated circuit (PMIC) that distributes power received from the external host to the controller 2002 and the semiconductor package 2003.

The controller 2002 may write data to or read data from the semiconductor package 2003 and may enhance the operational speed of the electronic system 2000.

The DRAM 2004 may act as buffer memory to mitigate the speed difference between the external host and the data storage space in the semiconductor package 2003. The DRAM 2004 included in the electronic system 2000 may also function as cache memory and provide temporary storage space during a control operation for the semiconductor package 2003. When the electronic system 2000 includes the DRAM 2004, the controller 2002 may further include a DRAM controller in addition to a NAND controller for controlling the DRAM 2004.

The semiconductor package 2003 may include first and second semiconductor packages 2003a and 2003b spaced apart from each other. Each of the first and second semiconductor packages 2003a and 2003b may include a plurality of semiconductor chips 2200. Each of the first and second semiconductor packages 2003a and 2003b may include a package substrate 2100, semiconductor chips 2200 on the package substrate 2100, adhesive layers 2300 disposed on the lower surfaces of the semiconductor chips 2200, connection structures 2400 electrically connecting the semiconductor chips 2200 to the package substrate 2100, and a molding layer 2500 covering the semiconductor chips 2200 and the connection structures 2400 on the package substrate 2100.

The package substrate 2100 may be a printed circuit board (PCB) including upper pads 2130. Each of the semiconductor chips 2200 may include input/output pads 2210. The input/output pads 2210 may correspond to the input/output pads 1101 illustrated in FIG. 1. Each of the semiconductor chips 2200 may include stacked structures 3210 and vertical structures 3220. Each of the semiconductor chips 2200 may include a semiconductor device according to embodiments of the present disclosure to be described below.

In some embodiments, the connection structures 2400 may be bonding wires electrically connecting the input/output pads 2210 and the upper pads 2130. Accordingly, in each of the first and second semiconductor packages 2003a and 2003b, the semiconductor chips 2200 may be electrically connected to each other via bonding wires and electrically connected to the upper pads 2130 of the package substrate 2100. In some embodiments, instead of bonding wires, the semiconductor chips 2200 in each of the first and second semiconductor packages 2003a and 2003b may be electrically connected to each other through connection structures including through-silicon vias (TSVs).

In some embodiments, the controller 2002 and the semiconductor chips 2200 may be included in a single package. In an exemplary embodiment, the controller 2002 and the semiconductor chips 2200 may be mounted on a different separate interposer substrate from the main board 2001, and the controller 2002 and the semiconductor chips 2200 may be interconnected via wires formed on the interposer substrate.

A case where the semiconductor chips 2200 are NAND flash memory devices will hereinafter be described as an example. However, the semiconductor chips 2200 included in each of the first and second semiconductor packages 2003a and 2003b are not limited to NAND flash memory devices and may also be volatile memory devices such as DRAMs.

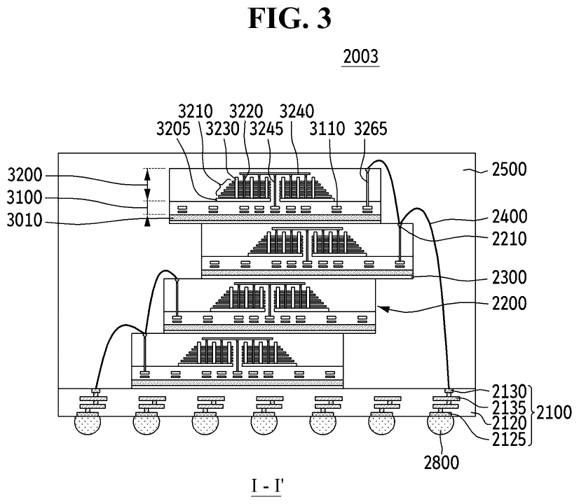

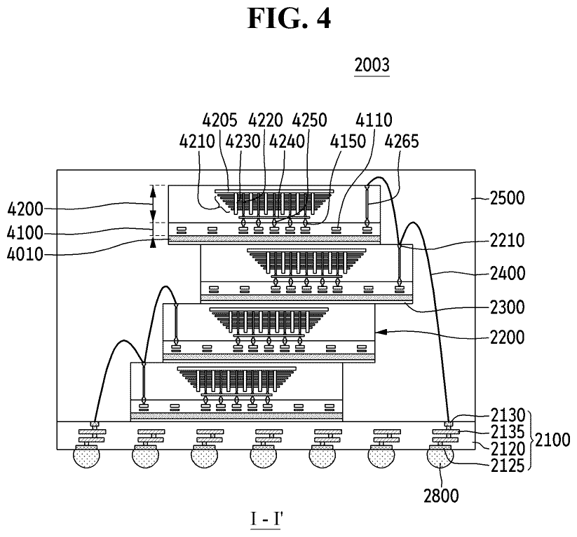

FIGS. 3 and 4 are cross-sectional views schematically illustrating semiconductor packages according to some embodiments of the present disclosure. FIGS. 3 and 4 illustrate exemplary embodiments of the semiconductor package illustrated in FIG. 2, and schematically depict cross-sections taken along the cutting line I-I′ of the semiconductor package 2003 shown in FIG. 2.

Referring to a semiconductor package 2003 of FIG. 3, a package substrate 2100 may be a PCB. The package substrate 2100 may include a package substrate body 2120, upper pads (“2130” in FIG. 2) disposed on or exposed through the upper surface of the package substrate body 2120, lower pads 2125 disposed on or exposed through the lower surface of the package substrate body 2120, and internal wiring 2135 electrically connecting the upper pads 2130 and the lower pads 2125 inside the package substrate body 2120. The upper pads 2130 may be electrically connected to the connection structures 2400. The lower pads 2125 may be connected to the wiring patterns 2005 on the main board 2001 of the electronic system 2000, as illustrated in FIG. 2, through conductive connectors 2800.

Each of a plurality of semiconductor chips 2200 may include a semiconductor substrate 3010, a first structure 3100 stacked on the semiconductor substrate 3010, and a second structure 3200 stacked on the first structure 3100. The first structure 3100 may include a peripheral circuit region including peripheral wiring 3110. The second structure 3200 may include a source structure 3205, stacked structures 3210 on the source structure 3205, vertical structures 3220 and isolation structures 3230 penetrating the stacked structures 3210, bitlines 3240 electrically connected to the vertical structures 3220, and cell contact plugs (not illustrated) electrically connecting wordlines (“WL” in FIG. 1) of the stacked structures 3210.

Each of the semiconductor chips 2200 may include through wiring 3245 electrically connected to the peripheral wiring 3110 of the first structure 3100 and extending into the second structure 3200. The through wiring 3245 may be arranged outside the stacked structures 3210 and may also penetrate the stacked structures 3210. Each of the semiconductor chips 2200 may further include input/output contact plugs 3265 electrically connected to the peripheral wiring 3110 of the first structure 3100 and input/output pads 2210 electrically connected to the input/output contact plugs 3265.

Referring to a semiconductor package 2003 of FIG. 4, a plurality of semiconductor chips 2200 may each include a semiconductor substrate 4010, a first structure 4100 on the semiconductor substrate 4010, and a second structure 4200 bonded to the first structure 4100 through wafer bonding.

The first structures 4100 may each include a peripheral circuit region including peripheral wiring 4110 and first bonding structures 4150. The second structures 4200 may each include a source structure 4205, stacked structures 4210 between the source structure 4205 and the corresponding first structure 4100, vertical structures 4220 and isolation structures 4230 penetrating the stacked structures 4210, bitlines 4240 electrically connected to the vertical structures 4220, and second bonding structures 4250 electrically connected to wordlines (“WL” in FIG. 1) of the stacked structures 4210. For example, the second bonding structures 4250 may be electrically connected to the vertical structures 4220 and the wordlines WL via the bitlines 4240, electrically connected to the vertical structures 4220, and cell contact plugs (not illustrated), electrically connected to the wordlines WL. The first bonding structures 4150 of the first structures 4100 and the second bonding structures 4250 of the second structures 4200 may be bonded together by being in direct contact with each other. The bonded portions of the first bonding structures 4150 and the second bonding structures 4250 may include, for example, copper (Cu).

Each of the semiconductor chips 2200 may further include input/output contact plugs 4265 electrically connected to the peripheral wiring 4110 of the first structure 4100 and input/output pads 2210 electrically connected to the input/output contact plugs 4265.

The semiconductor chips 2200 in FIG. 3 or FIG. 4 may be electrically connected to each other via connection structures 2400 in the form of bonding wires. However, in some embodiments, in a single semiconductor package, the semiconductor chips 2200 of FIG. 3 or 4 may be electrically connected to each other via connection structures including TSVs.

The first structures 3100 in FIG. 3 and the first structures 4100 in FIG. 4 may correspond to a peripheral circuit structure PS to be described below, and the second structures 3200 in FIG. 3 and the second structures 4200 in FIG. 4 may correspond to a cell structure CS to be described below.

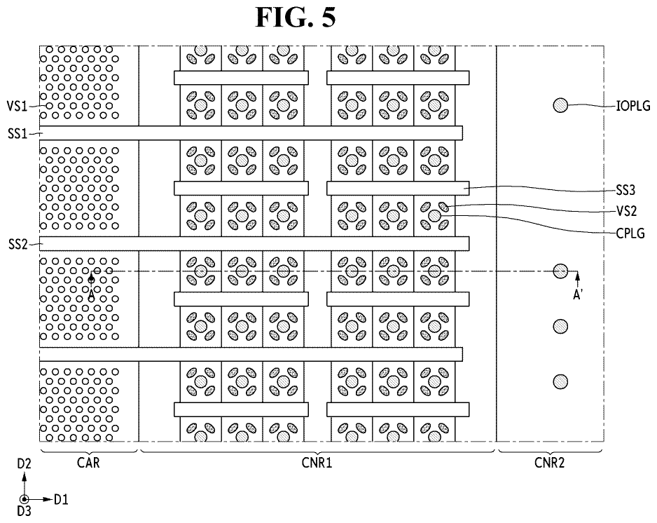

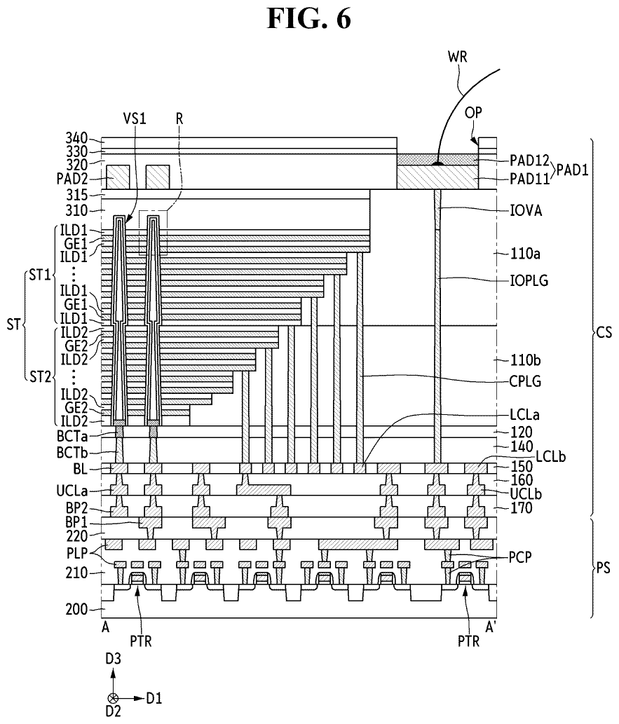

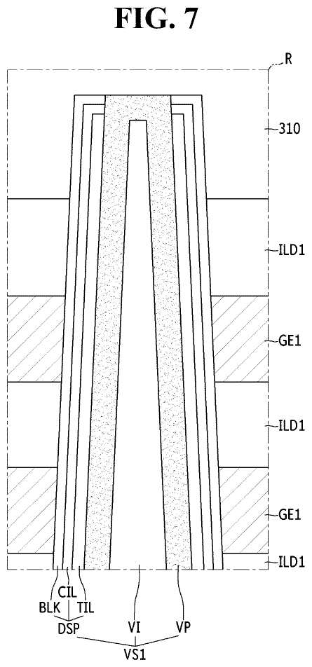

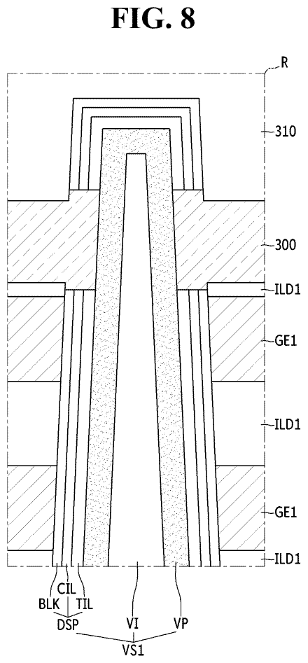

FIG. 5 is a plan view of a semiconductor device according to some embodiments of the present disclosure. FIG. 6 is a cross-sectional view, taken along line A-A′ of FIG. 5, of the semiconductor device according to some embodiments of the present disclosure. FIGS. 7 and 8 are exemplary enlarged cross-sectional views illustrating region R of FIG. 6.

Referring to FIGS. 5 and 6, the semiconductor device according to some embodiments of the present disclosure may include a peripheral circuit structure PS on a semiconductor substrate 200 and a cell structure CS on the peripheral circuit structure PS.

By coupling the cell structure CS onto the peripheral circuit structure PS, the cell density per unit area of the semiconductor device according to some embodiments of the present disclosure can be increased. Additionally, by fabricating the peripheral circuit structure PS and the cell structure CS separately and then combining the peripheral circuit structure PS and the cell structure CS, damage to peripheral circuits PTR caused by various thermal processes can be prevented, thereby improving the electrical characteristics and reliability of the semiconductor device according to some embodiments of the present disclosure.

The peripheral circuit structure PS may correspond to the first structures 3100 in FIG. 3 and the first structures 4100 in FIG. 4. Specifically, the peripheral circuit structure PS may include a semiconductor substrate 200, peripheral circuits PTR for controlling a memory cell array, and peripheral circuit insulating films 210 and 220 covering the peripheral circuits PTR. The peripheral circuits PTR may be disposed on the upper surface of the semiconductor substrate 200. Although not explicitly illustrated, a surface insulating film (not illustrated) may be provided on the backside of the semiconductor substrate 200.

The semiconductor substrate 200 may correspond to the semiconductor substrate 3010 in FIG. 3 and the semiconductor substrate 4010 in FIG. 4. The semiconductor substrate 200 may be, for example, a silicon substrate, a silicon-germanium substrate, a germanium substrate, or a monocrystalline epitaxial layer grown on a monocrystalline silicon substrate. The semiconductor substrate 200 may have an upper surface parallel to a first direction D1, a second direction D2 perpendicular to the first direction D1, and a third direction D3 perpendicular to the upper surface. The first to third directions D1, D2, and D3 may be mutually orthogonal directions.

The peripheral circuits PTR may include row and column decoders, page buffers, and control circuits. Specifically, the peripheral circuits PTR may include NMOS and PMOS transistors. Peripheral circuit wiring PLP may be electrically connected to the peripheral circuits PTR via peripheral plugs PCP.

The width, in a first direction D1 or a second direction D2, of the peripheral plugs PCP may, for example, increase along a third direction D3. The peripheral plugs PCP and the peripheral circuit wiring PLP may include a conductive material such as a metal.

The peripheral circuit insulating films 210 and 220 may be provided on the upper surface of the semiconductor substrate 200. The peripheral circuit insulating films 210 and 220 may cover the peripheral circuits PTR, the peripheral plugs PCP, and the peripheral circuit wiring PLP on the semiconductor substrate 200. The peripheral plugs PCP and the peripheral circuit wiring PLP may be electrically connected to the peripheral circuits PTR. The peripheral circuit insulating films 210 and 220 may include silicon oxide films, silicon nitride films, silicon oxynitride films, and/or low-k films.

First bonding pads BP1 may be positioned in the uppermost peripheral circuit insulating film 220. The uppermost peripheral circuit insulating film 220 may not cover the upper surfaces of the first bonding pads BP1. The upper surface of the uppermost peripheral circuit insulating film 220 may form a substantially coplanar surface with the upper surfaces of the first bonding pads BP1. The first bonding pads BP1 may be electrically connected to the peripheral circuits PTR via the peripheral circuit wiring PLP and the peripheral plugs PCP.

The cell structure CS may be provided on the peripheral circuit structure PS. The cell structure CS may correspond to the second structures 3200 in FIG. 3 and the second structures 4200 in FIG. 4. The cell structure CS may include a cell array region CAR (e.g., illustrated in FIG. 5) and first and second connection regions CNR1 and CNR2 (e.g., illustrated in FIG. 5). The first connection region CNR1 may be located between the cell array region CAR and the second connection region CNR2 in the first direction D1. The second connection region CNR2 may be located at the edge of the cell array region CAR and the first connection region CNR1. In some embodiments, the cell array region CAR and/or the first connection region CNR1 may be referred to as a first region, and the second connection region CNR2 may be referred to as a second region. In some embodiments, the term “edge” may refer to the closest area to the outer surface of each of the semiconductor chips 2200 in FIGS. 3 and 4.

The cell structure CS may include a memory cell array with memory cells arranged in three dimensions. Specifically, the cell structure CS may include a cell substrate 310, a stacked structures ST, first vertical structures VS1, bitlines BL, cell contact plugs CPLG, and an input/output contact plug IOPLG.

The cell substrate 310 may include a semiconductor substrate such as a silicon (Si) substrate, a germanium (Ge) substrate, or a silicon-germanium (SiGe) substrate. Alternatively, the cell substrate 310 may include a silicon-on-insulator (SOI) substrate or a germanium-on-insulator (GOI) substrate.

A plurality of stacked structures ST may be provided. The stacked structures ST may correspond to the stacked structures 3210 in FIG. 3 and the stacked structures 4210 in FIG. 4.

The stacked structures ST may extend along the first direction D1 and may be spaced apart in the second direction D2 from the planar perspective of FIG. 5. For convenience, the following description focuses on a single stacked structure ST, but may also be directly applicable to other stacked structures ST.

A stacked structure ST may include conductive patterns (GE1 and GE2) and interlayer insulating films (ILD1 and ILD2) that are alternately stacked along the third direction D3, which is perpendicular to the first and second directions D1 and D2.

In some embodiments, the conductive patterns (GE1 and GE2) may include first and second erase gate patterns adjacent to the cell substrate 310, ground selection gate patterns on the second erase gate patterns, a plurality of cell gate patterns stacked on the ground selection gate patterns, and string selection gate patterns on the uppermost cell gate patterns.

The conductive patterns (GE1 and GE2) of the stacked structure ST may form an inverted staircase structure in the first connection region CNR1. Specifically, the length, in the first direction D1, of the conductive patterns (GE1 and GE2) may increase in a direction away from the peripheral circuit structure PS.

The conductive patterns (GE1 and GE2) may each include a pad portion in the first connection region CNR1. The pad portions of the conductive patterns (GE1 and GE2) may be exposed through adjacent interlayer insulating films (ILD1 and ILD2). The pad portions of the conductive patterns (GE1 and GE2) may be located at different horizontal and vertical positions. The cell contact plugs CPLG may be connected to the pad portions of the conductive patterns (GE1 and GE2).

In some embodiments, the stacked structure ST may include a first stacked structure ST1 and a second stacked structure ST2 below the first stacked structure ST1. The first stacked structure ST1 may include first interlayer insulating films ILD1 and first conductive patterns GE1 that are alternately stacked, and the second stacked structure ST2 may include second interlayer insulating films ILD2 and second conductive patterns GE2 that are alternately stacked.

The second stacked structure ST2 may be positioned between the first stacked structure ST1 and the peripheral circuit structure PS. Specifically, the second stacked structure ST2 may be provided below the lowermost first interlayer insulating film ILD1 of the first stacked structure ST1. The uppermost second interlayer insulating film ILD2 of the second stacked structure ST2 may contact the lowermost first interlayer insulating film ILD1 of the first stacked structure ST1, but the present disclosure is not limited thereto. Alternatively, for example, a single insulating film may be provided between the uppermost second conductive pattern GE2 of the second stacked structure ST2 and the lowermost first conductive pattern GE1 of the first stacked structure ST1.

The lowermost second conductive pattern GE2 of the second stacked structure ST2 may have the smallest length in the first direction D1, and the uppermost first conductive pattern GE1 of the first stacked structure ST1 may have the largest length in the first direction D1.

The conductive patterns (GE1 and GE2) may include, for example, at least one of a doped semiconductor (e.g., doped silicon), a metal (e.g., tungsten, molybdenum, nickel, copper, aluminum), a conductive metal nitride (e.g., titanium nitride, tantalum nitride), or a transition metal (e.g., titanium, tantalum). The interlayer insulating films (ILD1 and ILD2) may include silicon oxide, silicon nitride, silicon oxynitride, and/or a low-k material. For example, the interlayer insulating films (ILD1 and ILD2) may include high-density plasma oxide (HDP oxide) or tetraethyl orthosilicate (TEOS).

The semiconductor device according to some embodiments of the present disclosure may be a vertical NAND flash memory device, in which case, the conductive patterns (GE1 and GE2) of the stacked structure ST may be used as the first lower gate lines LL1, the second lower gate lines LL2, the wordlines WL, the first upper gate lines UL1, and the second upper gate lines UL2 in FIG. 1.

A mold insulating film (110a and 110b) may cover the end (i.e., pad portion) of the stacked structure ST, which has a stepped structure. The mold insulating film (110a and 110b) may have a substantially flat upper surface. The mold insulating film (110a and 110b) may include a single insulating film or a plurality of stacked insulating films. For example, the mold insulating film (110a and 110b) may include a first mold insulating film 110a covering the stepped structure of the first stacked structure ST1 and a second mold insulating film 110b covering the stepped structure of the second stacked structure ST2. The mold insulating film (110a and 110b) may have substantially flat upper and lower surfaces. The upper surface of the mold insulating film (110a and 110b) may form a substantially coplanar surface with the upper surface of the uppermost interlayer insulating film ILD1 of the stacked structure ST, and the lower surface of the mold insulating film (110a and 110b) may form a substantially coplanar surface with the lower surface of the lowermost interlayer insulating film ILD2 of the stacked structure ST.

The cell substrate 310 may be arranged on the stacked structure ST and the mold insulating film (110a and 110b). The cell substrate 310 may cover the uppermost surfaces of the stacked structure ST and the mold insulating film (110a and 110b).

A plurality of first vertical structures VS1 may penetrate the stacked structure ST in the cell array region CAR. The first vertical structures VS1 may correspond to the vertical structures 3220 in FIG. 3 and the vertical structures 4220 in FIG. 4.

The first vertical structures VS1 may extend into the cell substrate 310. The first vertical structures VS1 may be arranged in one direction or in a zigzag pattern from a planar perspective. Second vertical structures VS2 may be formed in the first and second connection regions CNR1 and CNR2 with a shape similar to that of the first vertical structures VS1 to alleviate stress applied to the mold insulating film (110a and 110b). The second vertical structures VS2 may have substantially the same structure and include the same materials as the first vertical structures VS1. The planar shape and size of the second vertical structures VS2 may differ from those of the first vertical structures VS1. The upper surfaces of the second vertical structures VS2 may have various shapes such as circular, oval, or bar-like.

In some embodiments, the first vertical structures VS1 may be provided in vertical channel holes penetrating the stacked structure ST. In some embodiments, each of the vertical channel holes may include a first vertical channel hole penetrating the first stacked structure ST1 and a second vertical channel hole penetrating the second stacked structure ST2 and connected to the first vertical channel hole.

Each of the first vertical structures VS1 may include a first vertical extension in the first vertical channel hole and a second vertical extension in the second vertical channel hole. The first and second vertical extensions may be a single structure continuously extending without an interface. The first vertical extension may have a sidewall with a uniform slope from its bottom to its top. Similarly, the second vertical extension may have a sidewall with a uniform slope from its bottom to its top. That is, the width, in the first or second direction D1 or D2, of each of the first and second vertical extensions may decrease in a direction away from the semiconductor substrate 200. The first and second vertical extensions may have different diameters at the point where they are connected. A step difference may be formed at the connection between the first and second vertical extensions.

However, the present disclosure is not limited to this. Unlike what is illustrated, each of the first vertical structures VS1 may include three or more vertical extensions, forming a step difference at two or more boundaries. As another example, each of the first vertical structures VS1 may have a flat sidewall with no step difference.

As illustrated in FIGS. 7 and 8, each of the first vertical structures VS1 may include a vertical channel pattern VP, a data storage pattern DSP, and a vertical insulating pattern VI.

The vertical channel pattern VP may extend in the third direction D3 and penetrate the stacked structure ST. The vertical channel pattern VP is illustrated as having a cup shape, but this is merely exemplary. For example, the vertical channel pattern VP may have various other shapes, such as a cylindrical shape, a rectangular prism shape, or a solid filler shape.

The vertical channel pattern VP may include, for example, a semiconductor material such as monocrystalline Si, polycrystalline Si, an organic semiconductor material, or a carbon nanostructure, but is not limited thereto.

The data storage pattern DSP may be interposed between the vertical channel pattern VP and each of the conductive patterns (GE1 and GE2). For example, the data storage pattern DSP may extend along the side surface of the vertical channel pattern VP.

The data storage pattern DSP may include, for example, at least one of silicon oxide, silicon nitride, silicon oxynitride, or a high-k material with a greater dielectric constant than silicon oxide. The high-k material may include, for example, aluminum oxide, hafnium oxide, lanthanum oxide, tantalum oxide, titanium oxide, lanthanum hafnium oxide, lanthanum aluminum oxide, dysprosium scandium oxide, or a combination thereof.

In some embodiments, the data storage pattern DSP may be formed as a multilayer structure. For example, the data storage pattern DSP may include a tunneling insulating film TIL, a charge storage film CIL, and a blocking insulating film BLK sequentially stacked on the vertical channel pattern VP.

The tunneling insulating film TIL may include, for example, silicon oxide or a high-k material with a greater dielectric constant than silicon oxide, such as aluminum oxide (Al₂O₃) or hafnium oxide (HfO₂). The charge storage film CIL may include, for example, silicon nitride. The blocking insulating film BLK may include, for example, silicon oxide or a high-k material with a greater dielectric constant than silicon oxide, such as Al₂O₃ or HfO₂.

In some embodiments, each of the first vertical structures VS1 may further include a vertical insulating pattern VI. The vertical insulating pattern VI may be formed to fill the interior of a cup-shaped semiconductor pattern 130. The vertical insulating pattern VI may include an insulating material, such as silicon oxide, but is not limited thereto.

In some embodiments, the first vertical structures VS1 may be arranged in a zigzag pattern. For example, as illustrated in FIG. 2, the first vertical structures VS1 may be staggered in the first and second directions D2. The zigzag arrangement of the first vertical structures VS1 may further enhance the integration density of the semiconductor device according to some embodiments of the present disclosure.

As illustrated in FIG. 8, the semiconductor device according to some embodiments of the present disclosure may further include a source structure 300.

The source structure 300 may be formed on the cell substrate 310. The source structure 300 may be interposed between the cell substrate 310 and the stacked structure ST. The source structure 300 may include, for example, doped polysilicon or a metal.

In some embodiments, the first vertical structures VS1 may penetrate the source structure 300 to be connected to the cell substrate 310. For example, the lower portions of the first vertical structures VS1 may penetrate the source structure 300 to be embedded in the cell substrate 310. The source structure 300 may be formed to be connected with the vertical channel patterns VP of the first vertical structures VS1. For example, the source structure 300 may be connected with the vertical channel patterns VP of the first vertical structures VS1 through the data storage patterns DSP.

In some embodiments, a portion of the source structure 300 adjacent to the vertical channel patterns VP may protrude toward the data storage patterns DSP. For example, the length, in the third direction D3, of the source structure 300 may become greater in the region adjacent to the vertical channel patterns VP. This may result from an etching process that removes portions of the data storage patterns DSP during the formation of the source structure 300.

An upper insulating film 315 (e.g., illustrated in FIG. 6) may be arranged on the cell substrate 310. A pad structure PAD1 and upper pads PAD2 may be positioned on the upper insulating film 315. The pad structure PAD1 may correspond to the input/output pads 1101 in FIG. 1 and the input/output pads 2210 in FIGS. 3 and 4. The upper pads PAD2 may be arranged on the cell structure CS in the cell array region CAR and/or the first connection region CNR1. Details regarding the pad structure PAD1 will be described later.

A capping insulating film 320, a protective film 330, and a passivation layer 340 may be sequentially arranged on the front surface of the upper insulating film 315. The capping insulating film 320, the protective film 330, and the passivation layer 340 may be positioned on the cell structure CS. The capping insulating film 320, the protective film 330, and the passivation layer 340 may be positioned on the upper pads PAD2. Together, the capping insulating film 320, the protective film 330, and the passivation layer 340 may form an insulating layer on the upper insulating film 315.

The capping insulating film 320 may include, for example, silicon nitride or silicon oxynitride. When the capping insulating film 320 comprises silicon nitride, the thermal conductivity of the capping insulating film 320 may be in a range from 15 Watts/meter*Kelvin (W/m*K) to 90 W/m*K, and when the capping insulating film 320 comprises silicon oxynitride, the thermal conductivity of the capping insulating film 320 may be in a range from 1 W/m*K to 5 W/m*K. As such, the capping insulating film 320 may comprise a thermal conductivity in a range from 1 W/m*K to 90 W/m*K. The protective film 330 may include, for example, silicon nitride or silicon oxynitride. When the protective film 330 comprises silicon nitride, the thermal conductivity of the protective film 330 may be in a range from 15 W/m*K to 90 W/m*K, and when the protective film 330 comprises silicon oxynitride, the thermal conductivity of the protective film 330 may be in a range from 1 W/m*K to 5 W/m*K. As such, the protective film 330 may comprise a thermal conductivity in a range from 1 W/m*K to 90 W/m*K. The passivation layer 340 may include a polyimide-based material, such as photosensitive polyimide (PSPI). When the passivation layer 340 comprises photosensitive polyimide (PSPI), the thermal conductivity of the passivation layer 340 may be in a range from 0.1 W/m*K to 0.5 W/m*K.

The capping insulating film 320, the protective film 330, and the passivation layer 340 may include an opening OP that exposes a portion of the pad structure PAD1. Accordingly, the opening OP may be formed in the insulating layer (e.g., the capping insulating film 320, the protective film 330, and the passivation layer 340), and the opening OP may expose the insulating film 110a and the input/output via IOVA.

A first insulating film 120 may be arranged below the second mold insulating film 110b and the stacked structure ST. The first insulating film 120 may cover the lower surfaces of the first vertical structures VS1.

First isolation structures SS1, a second isolation structure SS2, and third isolation structures SS3 of FIG. 5 may each extend in the first direction D1. Although not specifically illustrated, the first isolation structures SS1, the second isolation structure SS2, and the third isolation structures SS3 may penetrate the mold insulating film (110a and 110b) and the stacked structure ST. The first isolation structures SS1, the second isolation structure SS2, and the third isolation structures SS3 may correspond to the isolation structures 3230 in FIG. 3 and the isolation structures 4230 in FIG. 4. The first isolation structures SS1, the second isolation structure SS2, and the third isolation structures SS3 may include an insulating material such as silicon oxide, silicon oxynitride, or silicon nitride.

The first isolation structures SS1 may extend in the first direction D1 from the cell array region CAR to the first connection region CNR1 and may be spaced apart in the second direction D2. In some embodiments, the stacked structure ST may be positioned between adjacent first isolation structures SS1 in the second direction D2.

The second isolation structure SS2 may penetrate the stacked structure ST in the cell array region CAR. The second isolation structure SS2 may be positioned between the first isolation structures SS1. In the first direction D1, the length of the second isolation structure SS2 may be smaller than that of the first isolation structures SS1. Alternatively, a plurality of second isolation structures SS2 may be provided between the first isolation structures SS1.

The third isolation structures SS3 may be spaced apart from the first isolation structures SS1 and second isolation structure SS2 in the first connection region CNR1 and may penetrate the mold insulating film (110a and 110b) and the stacked structure ST. The third isolation structures SS3 may extend along the first direction D1. The third isolation structures SS3 may be spaced apart in the second direction D2.

A second insulating film 140 may be positioned below the first insulating film 120. Bitline conductive pads may be formed at the lower ends of the first vertical structures VS1, and lower bitline contact plugs BCTa may penetrate the first insulating film 120 to contact the bitline conductive pads. The bitline conductive pads may include an undoped semiconductor material, a doped semiconductor material, or a conductive material. Upper bitline contact plugs BCTb may penetrate the second insulating film 140 to be connected with the lower bitline contact plugs BCTa.

In the first connection region CNR1, cell contact plugs CPLG may penetrate the first and second insulating films 120 and 140 and the mold insulating film (110a and 110b) to be connected with the pad portions of the conductive patterns (GE1 and GE2). The lengths, in the third direction D3, of the cell contact plugs CPLG may decrease in a direction closer to the cell array region CAR. The lower surfaces of the cell contact plugs CPLG may form a substantially coplanar surface.

The input/output contact plug IOPLG may extend in the third direction D3 within the cell structure CS. The input/output contact plug IOPLG may penetrate the first and second insulating films 120 and 140 and the first and second mold insulating films 110a and 110b in the second connection region CNR2. The input/output contact plug IOPLG may correspond to the input/output connection wiring 1135 in FIG. 1, the input/output contact plugs 3265 in FIG. 3, and the input/output contact plugs 3265 in FIG. 4. Although only one input/output contact plug IOPLG is illustrated in FIG. 6, the number of input/output contact plugs IOPLG is not particularly limited, and a plurality of input/output contact plugs IOPLG may be formed. In some embodiments, the input/output contact plug IOPLG may be referred to as a TSV.

The input/output contact plug IOPLG may further extend upward beyond the cell substrate 310. An input/output via IOVA may extend further upward beyond the upper insulating film 315. The input/output contact plug IOPLG may be electrically connected to the pad structure PAD1 through the input/output via IOVA.

The cell contact plugs CPLG and the input/output contact plug IOPLG may each include a barrier pattern comprising a conductive metal nitride (e.g., titanium nitride or tantalum nitride) and a metal pattern comprising a metal (e.g., tungsten, titanium, or tantalum).

The bitlines BL may be positioned below the second insulating film 140 in the cell array region CAR. The bitlines BL may correspond to the bitlines BL in FIG. 1, the bitlines 3240 in FIG. 3, and the bitlines 4240 in FIG. 4.

The bitlines BL may extend across the stacked structure ST in the second direction D2. The bitlines BL may be electrically connected to the first vertical structures VS1 through the lower bitline contact plugs BCTa and upper bitline contact plugs BCTb.

First lower conductive lines LCLa may be positioned below the second insulating film 140 in the first connection region CNR1 and may be connected to the cell contact plugs CPLG. Second lower conductive lines LCLb may be positioned below the second insulating film 140 in the second connection region CNR2 and may be connected to the input/output contact plug IOPLG.

A third insulating film 150 may be positioned below the second insulating film 140, and the bitlines BL, the first lower conductive lines LCLa, and the second lower conductive lines LCLb may be positioned within the third insulating film 150.

A fourth insulating film 160 may be positioned below the third insulating film 150, and first upper conductive lines UCLa and second upper conductive lines UCLb may be positioned within the fourth insulating film 160. The first upper conductive lines UCLa may be electrically connected to the bitlines BL in the cell array region CAR. The second upper conductive lines UCLb may be electrically connected to the first lower conductive lines LCLa and the second lower conductive lines LCLb in the first and second connection regions CNR1 and CNR2.

The first lower conductive lines LCLa, the second lower conductive lines LCLb, the first upper conductive lines UCLa, and the second upper conductive lines UCLb may include at least one material selected from a metal (e.g., tungsten, copper, or aluminum), a conductive metal nitride (e.g., titanium nitride or tantalum nitride), or a transition metal (e.g., titanium or tantalum). For example, the first lower conductive lines LCLa and the second lower conductive lines LCLb may include tungsten, which has relatively high electrical resistivity, and the first upper conductive lines UCLa and the second upper conductive lines UCLb may include copper, which has relatively low electrical resistivity.

A fifth insulating film 170 may be positioned below the fourth insulating film 160, and second bonding pads BP2 may be positioned within the fifth insulating film 170. The second bonding pads BP2 may be electrically connected to the first upper conductive lines UCLa and the second upper conductive lines UCLb. The second bonding pads BP2 may include aluminum, copper, or tungsten.

The second bonding pads BP2 may be electrically and physically connected to the first bonding pads BP1 through a bonding method. Specifically, the second bonding pads BP2 may directly contact the first bonding pads BP1. In one embodiment, the first bonding pads BP1 and the second bonding pads BP2 may be integrally formed without boundaries. The second bonding pads BP2 may include the same metal material as the first bonding pads BP1. The second bonding pads BP2 may have substantially the same shape, width, or area as the first bonding pads BP1.

Referring to FIG. 6, the pad structure PAD1 may be positioned in the second connection region CNR2 and connected to the input/output contact plug IOPLG.

The pad structure PAD1 may include a first via pad PAD11 connected to the input/output contact plug IOPLG (e.g., through the input/output via IOVA) and a first heat conductive pad PAD12 positioned within a first opening OP above the first via pad PAD11. The first heat conductive pad PAD12 may be in thermal communication with the first via pad PAD11.

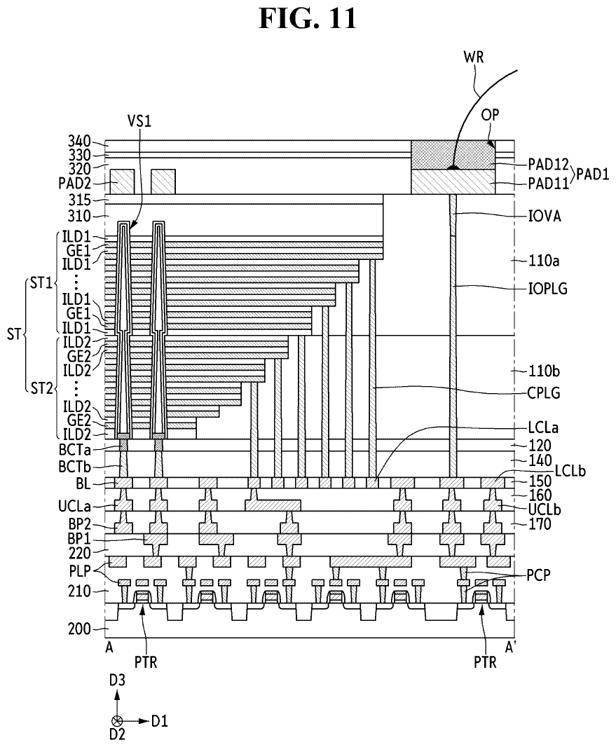

The first opening OP may extend through the passivation layer 340, the protective film 330, and the capping insulating film 320. The first opening OP may be surrounded by, and may expose, the inner sidewalls of the passivation layer 340, the inner sidewalls of the protective film 330, and the inner sidewalls of the capping insulating film 320. A bottom of the first opening OP may be bordered by an upper surface of the first mold insulating film 110a. The first via pad PAD11 may be positioned in the first opening OP such that a portion of the first via pad PAD11, for example, an upper surface of the first via pad PAD11, may be exposed in relation to the capping insulating film 320 (e.g., not covered by the capping insulating film 320). In some embodiments, the first via pad PAD11 may be in contact with the upper surface of the first mold insulating film 110a and may be in contact with the inner sidewall of the capping insulating film 320. The first via pad PAD11 may fill a lower portion of the first opening OP. The first heat conductive pad PAD12 may be positioned within the first opening OP on the first via pad PAD11. In some embodiments, the first heat conductive pad PAD12 may partially fill the first opening OP. For example, the first heat conductive pad PAD12 may be in contact with an upper surface of the first via pad PAD11 and may be in contact with one or more of the inner sidewalls. For example, as illustrated in FIG. 6, the first heat conductive pad PAD12 may be in contact with the inner sidewalls of the capping insulating film 320, while an upper surface of the first heat conductive pad PAD12 may be below the protective film 330 and the passivation layer 340, such that the first heat conductive pad PAD12 may not be in contact with the inner sidewalls of the protective film 330 or the passivation layer 340. However, in other embodiments (e.g., as illustrated in FIG. 11), the first heat conductive pad PAD12 may comprise a thickness that is greater than the thickness illustrated in FIG. 6, such that the first heat conductive pad PAD12 may contact the inner sidewalls of the protective film 330 and the passivation layer 340. The first opening OP may be formed by patterning portions of the capping insulating film 320, the protective film 330, and the passivation layer 340.

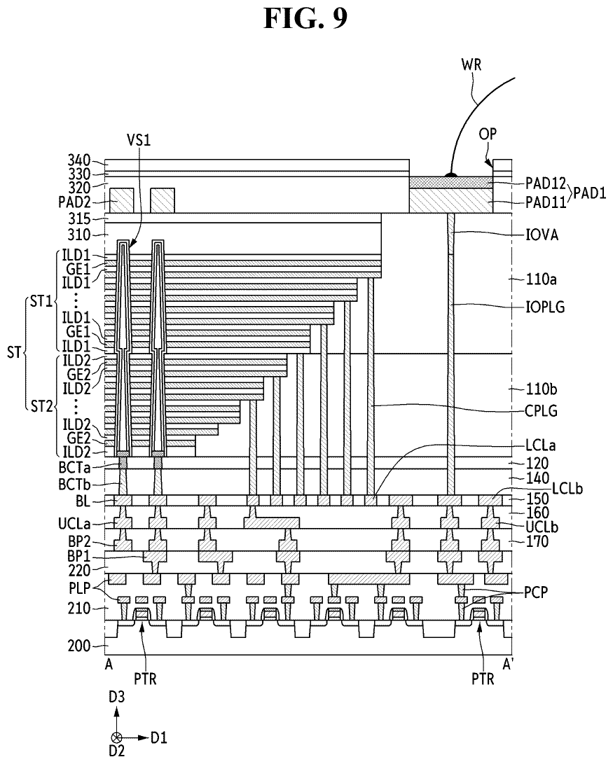

A bonding wire WR may be positioned on the pad structure PAD1. The bonding wire WR may be arranged between the first via pad PAD11 and the first heat conductive pad PAD12. For example, the first opening OP may be formed first (e.g., by patterning (e.g., removing) portions of the capping insulating film 320, the protective film 330, and the passivation layer 340), followed by forming the first via pad PAD11 within the first opening OP. After formation of the first via pad PAD11, the bonding wire WR may be connected to the first via pad PAD11, for example, with the bonding wire WR connected to an upper surface of the first via pad PAD11. For example, the bonding wire WR may be connected to the first via pad PAD11 such that the bonding wire WR may be electrically connected to the first via pad PAD11. In some embodiments, the bonding wire WR may comprise a deformed portion and a non-deformed portion. The deformed portion may be the portion of the bonding wire WR that is connected to, and in contact with, the first via pad PAD11. The deformed portion may be flattened or physically altered to form an electrical and structural connection with the first via pad PAD11. The non-deformed portion of the bonding wire WR may not be flattened or physically altered, and, instead, may retain its original shape (e.g., a circular cross-section, for example), and the non-deformed portion may be connected to the deformed portion, such that the deformed portion and the non-deformed portion may, together, form the bonding wire WR. When the deformed portion of the bonding wire WR is electrically and structurally connected to the first via pad PAD11, the non-deformed portion may not be in contact with the first via pad PAD11. Accordingly, when the bonding wire WR is described herein as being connected to the pad structure PAD1, the deformed portion of the bonding wire WR may be connected to, and in contact with, either the first via pad PAD11 (e.g., as illustrated in FIG. 6) or the first heat conductive pad PAD12 (e.g., as illustrated in FIG. 9).

After wire bonding, the first heat conductive pad PAD12 may be formed. The bonding wire WR may be positioned on the upper surface of the first via pad PAD11, and the first heat conductive pad PAD12 may be formed over the first via pad PAD11 and the portion of the bonding wire WR that is connected to the first via pad PAD11. As such, the deformed portion of the bonding wire WR that is connected to the first via pad PAD11 may be between the first via pad PAD11 and the first heat conductive pad PAD12. The pad structure PAD1 may be connected to the input/output contact plug IOPLG through the input/output via IOVA.

The bonding wire WR may correspond to the connection structures 2400 in FIGS. 3 and 4. However, as will be described below, the presence or absence of the bonding wire WR and the positional relationship between the bonding wire WR and the pad structure PAD1 are not limited to in the embodiment of FIG. 6.

The first via pad PAD11 may be formed from a metal material such as aluminum, copper, or tungsten. The first heat conductive pad PAD12 may be formed from various materials suitable for dissipating and thermally conducting heat from the semiconductor device according to some embodiments of the present disclosure. For example, the first heat conductive pad PAD12 may be provided in the form of a film but is not limited thereto.

For example, the first heat conductive pad (PAD12) may include at least one of a silicon-based material containing silicon, a ceramic-based material including aluminum oxide (Al2O3), boron nitride (BN), aluminum nitride (AlN), etc., a carbon-based material including graphite, carbon fiber, carbon nanotube, etc., a metal-based material including metal materials such as copper (Cu) and aluminum (Al), or a polyimide-based material including a polyimide film. However, the material of the first heat conductive pad (PAD12) is not limited thereto.

For example, when the first heat conductive pad (PAD12) includes a silicon-based material, the thermal conductivity of the first heat conductive pad (PAD12) may be 1 W/m*K to 10 W/m*K. For example, when the first heat conductive pad (PAD12) includes a carbon-based material, the thermal conductivity of the first heat conductive pad (PAD12) may be 50 W/m*K to 2000 W/m*K. For example, when the first heat conductive pad (PAD12) includes a metal-based material, the thermal conductivity of the first heat conductive pad (PAD12) may be 100 W/m*K to 500 W/m*K. However, the thermal conductivity of the first heat conductive pad (PAD12) is not limited thereto.

For example, when the first heat conductive pad (PAD12) includes a metal-based material such as copper (Cu), the first heat conductive pad (PAD12) may include a seed layer formed on the first via pad (PAD11) using PVD (Physical Vapor Deposition), CVD (Chemical Vapor Deposition), etc., and a plating layer formed on the seed layer using electroplating, etc. However, the method of forming the first heat conductive pad (PAD12) is not limited thereto.

For example, the thickness of the first heat conductive pad (PAD12) in the third direction (D3) may be less than or equal to the thickness of the first via pad (PAD11) in the third direction (D3). For example, the thickness of the first heat conductive pad (PAD12) in the third direction (D3) may be less than or equal to half the thickness of the first via pad (PAD11) in the third direction (D3), but is not limited thereto. For example, the length of the first heat conductive pad (PAD12) in the first direction (D1) may be the same as the length of the first via pad (PAD11) in the first direction (D1). For example, the length of the first heat conductive pad (PAD12) in the second direction (D2) may be the same as the length of the first via pad (PAD11) in the second direction (D2). However, the technical idea of the present invention is not limited thereto.

FIGS. 9 through 19 are cross-sectional views of the semiconductor device according to some embodiments of the present disclosure, and correspond to FIG. 6. For convenience of explanation, overlapping content with FIGS. 1 through 8 may be omitted.

Referring to FIG. 9, the bonding wire WR may not be arranged between the first via pad PAD11 and the first heat conductive pad PAD12. That is, after the first heat conductive pad PAD12 is formed, wire bonding may be performed. The first via pad PAD11 may not contact the bonding wire WR, but may be connected to the bonding wire WR by the first heat conductive pad PAD12. The bonding wire WR may be arranged on the upper surface of the first heat conductive pad PAD12, with the deformed portion of the bonding wire WR connected to the first heat conductive pad PAD12. The first heat conductive pad PAD12 may only partially fill the first opening OP. For example, in the third direction D3, the upper surface of the first heat conductive pad PAD12 may be positioned below the upper surfaces of the passivation layer 340 and the protective film 330. In other embodiments, the first heat conductive pad PAD12 may only partially fill the first opening OP, such that the upper surface of the first heat conductive pad PAD12 is positioned below the upper surface of the passivation layer 340, while the upper surface of the first heat conductive pad PAD12 is either co-planar with, or above, the upper surface of the protective film 330.

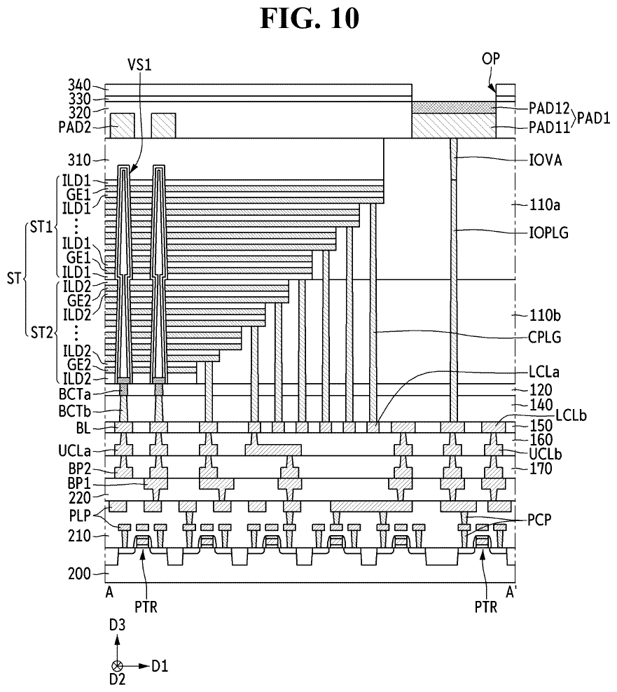

Referring to FIG. 10, the bonding wire WR may not be arranged on the pad structure PAD1. In this case, the pad structure PAD1 may not be connected via the bonding wire WR. Similar to the embodiment of FIG. 9, the first heat conductive pad PAD12 may only partially fill the first opening OP in the embodiment of FIG. 10.

Referring to FIG. 11, the first heat conductive pad PAD12 may completely fill the first opening OP. In the third direction D3, the upper surface of the first heat conductive pad PAD12 and the upper surface of the passivation layer 340 may be positioned at substantially the same level. For example, by being at the same level, the upper surface of the first heat conductive pad PAD12 may be co-planar with the upper surface of the passivation layer 340. Alternatively, the upper surface of the first heat conductive pad PAD12 may comprise a non-planar shape while still being at the same level as the upper surface of the passivation layer 340, for example, with the upper surface of the first heat conductive pad PAD12 lying within, or intersected by, a plane within which the upper surface of the passivation layer 340 lies. FIG. 11 illustrates the upper surfaces of the first heat conductive pad PAD12 and the passivation layer 340 as being at the same level, but the present disclosure is not limited thereto. For example, the upper surface of the first heat conductive pad PAD12 may slightly protrude beyond the upper surface of the passivation layer 340. For example, the first heat conductive pad PAD12 may completely fill the first opening OP, with the upper surface of the first heat conductive pad PAD12 being at a higher level than the upper surface of the passivation layer 340. For example, in some embodiments, an entirety of the upper surface of the first heat conductive pad PAD12 may be above the upper surface of the passivation layer 340, such that a plane, within which the upper surface of the passivation layer 340 lies, may intersect the first heat conductive pad PAD12, with the plane being below the upper surface of the first heat conductive pad PAD12. As described above relative to FIG. 6, the bonding wire WR (e.g., the portion of the bonding wire WR that is connected to the first via pad PAD11) may be arranged between the first via pad PAD11 and the first heat conductive pad PAD12. Accordingly, after wire bonding, the first heat conductive pad PAD12 may be formed.

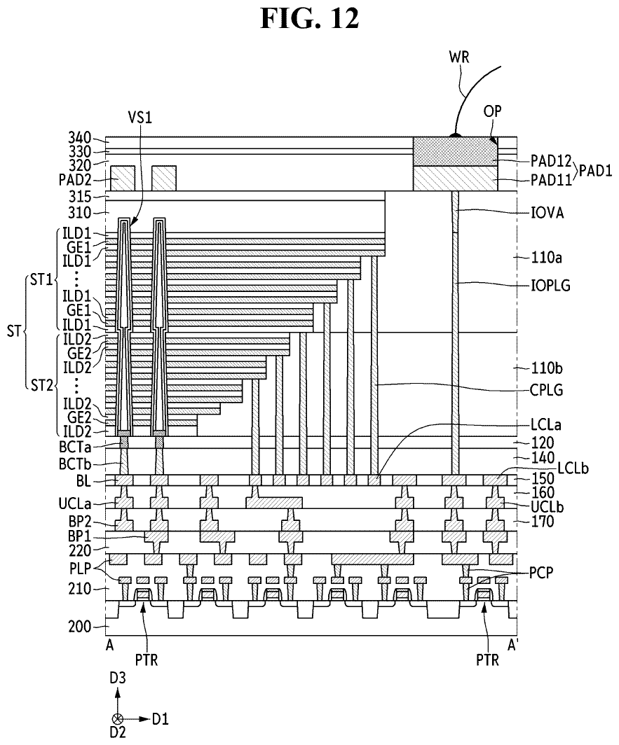

FIG. 12 illustrates the first heat conductive pad PAD12 completely filling the first opening OP in an identical manner as described above relative to FIG. 11. Referring to FIG. 12, the bonding wire WR may not be arranged between the first via pad PAD11 and the first heat conductive pad PAD12. For example, after the first heat conductive pad PAD12 is formed, wire bonding may be performed. The first via pad PAD11 may not contact the bonding wire WR, and the first heat conductive pad PAD12 may be connected to the bonding wire WR. The deformed portion of the debonding wire WR may be connected to the upper surface of the first heat conductive pad PAD12 in an identical manner as described above relative to FIG. 9. The bonding wire WR may be arranged on both the upper surface of the first heat conductive pad PAD12 and the upper surface of the passivation layer 340, or the bonding wire WR may be connected to the upper surface of the first heat conductive pad PAD12 without being in contact with the upper surface of the passivation layer 340. The first heat conductive pad PAD12 may completely fill the first opening OP in an identical manner to the embodiment described above in FIG. 11. In the third direction D3, the upper surfaces of the first heat conductive pad PAD12 and the passivation layer 340 may be positioned at substantially the same level, or the upper surface of the first heat conductive pad PAD12 may be at a higher level than an upper surface of the passivation layer 340.

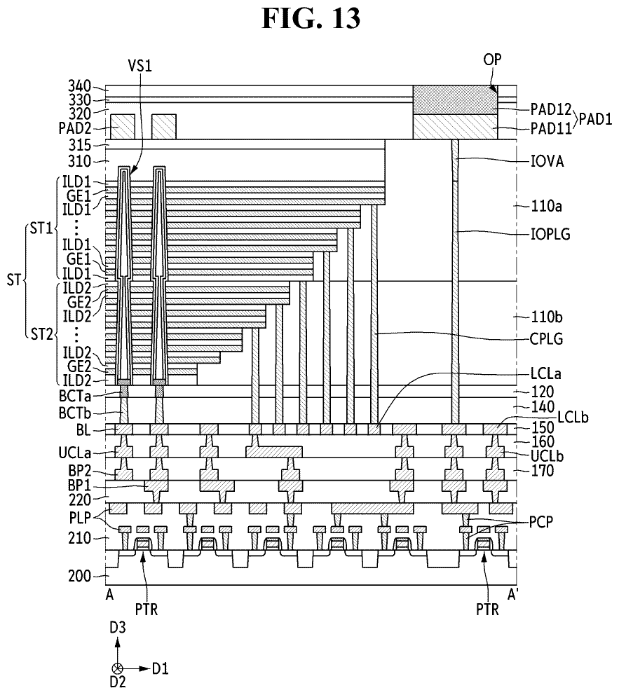

Referring to FIG. 13, the bonding wire WR may not be arranged on the pad structure PAD1. In this case, the pad structure PAD1 may not be connected via the bonding wire WR. Similar to the embodiments of FIGS. 11 and 12, the first heat conductive pad PAD12 may completely fill the first opening OP in the embodiment of FIG. 13.

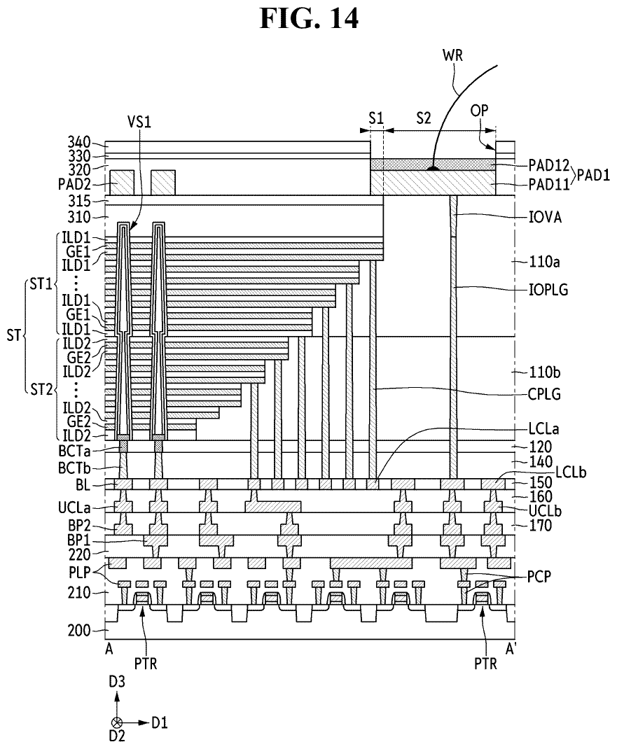

Referring to FIG. 14, the pad structure PAD1 may include a first region S1 overlapping the cell array region CAR and/or the first connection region CNR1, and a second region S2 overlapping the second connection region CNR2. The pad structure PAD1 may extend in a direction parallel to the first direction D1 to at least partially overlap the cell array region CAR and/or the first connection region CNR1. After wire bonding, the first heat conductive pad PAD12 may be formed, such that the positional relationship between the first heat conductive pad PAD12, the bonding wire WR, and the first via pad PAD11 in FIG. 14 may be identical to the positional relationship illustrated and described relative to FIG. 6, but for the first region S1 overlapping the cell array region CAR and/or the first connection region CNR1 in FIG. 14. The first heat conductive pad PAD12 may only partially fill the first opening OP.

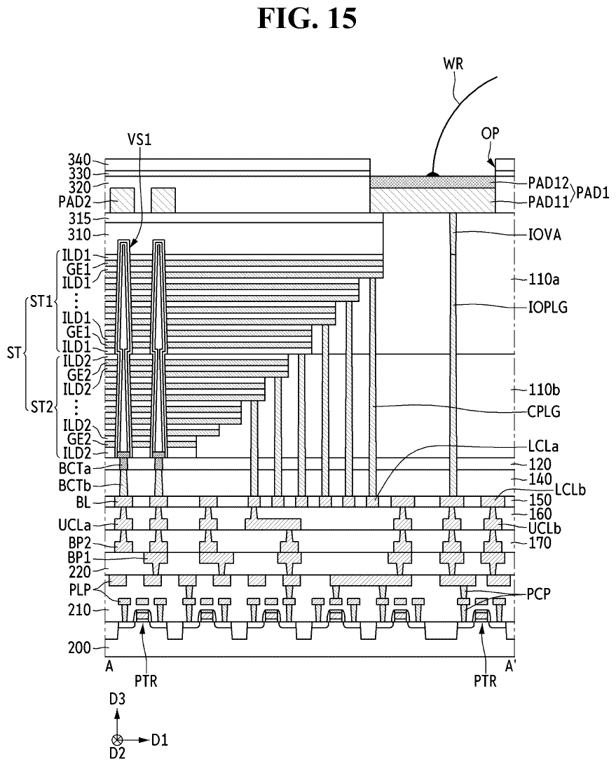

Referring to FIG. 15, after the first heat conductive pad PAD12 is formed, wire bonding may be performed. The pad structure PAD1 may extend in a direction parallel to the first direction D1 to at least partially overlap the cell array region CAR and/or the first connection region CNR1. The first heat conductive pad PAD12 may only partially fill the first opening OP. As such, the positional relationship between the first heat conductive pad PAD12, the bonding wire WR, and the first via pad PAD11 in FIG. 15 may be identical to the positional relationship illustrated and described relative to FIG. 9, but for the first region S1 overlapping the cell array region CAR and/or the first connection region CNR1 in FIG. 15.

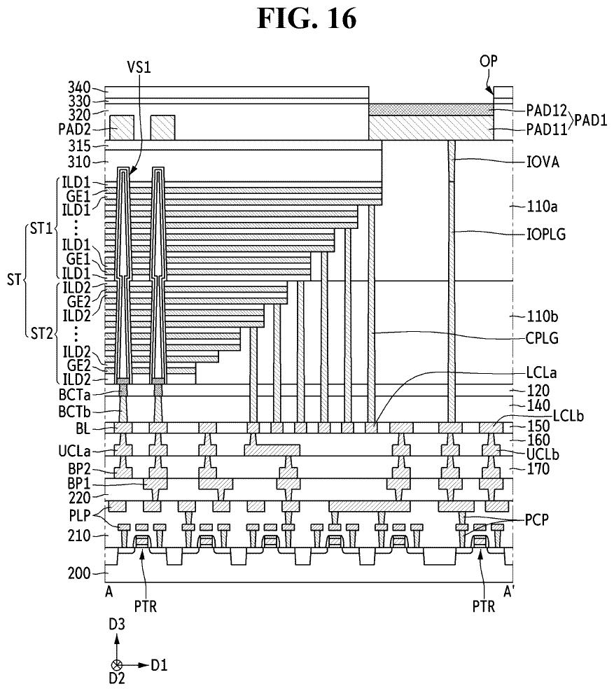

Referring to FIG. 16, the bonding wire WR may not be arranged on the pad structure PAD1. In this case, the pad structure PAD1 may not be connected via the bonding wire WR. The pad structure PAD1 may extend in a direction parallel to the first direction D1 to at least partially overlap the cell array region CAR and/or the first connection region CNR1. As such, the positional relationship between the first heat conductive pad PAD12, the bonding wire WR, and the first via pad PAD11 in FIG. 16 may be identical to the positional relationship illustrated and described relative to FIG. 10, but for the first region S1 overlapping the cell array region CAR and/or the first connection region CNR1 in FIG. 16.

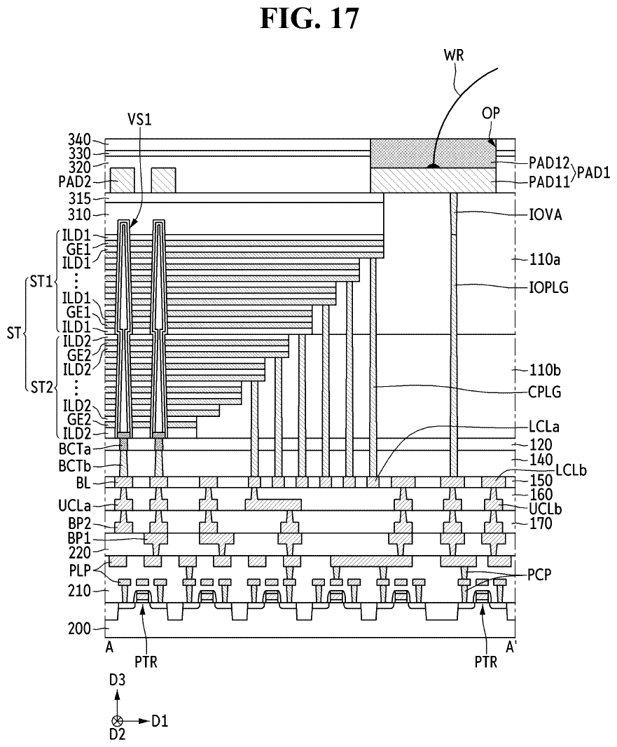

Referring to FIG. 17, the first heat conductive pad PAD12 may completely fill the first opening OP. The pad structure PAD1 may include a first region S1 overlapping the cell array region CAR and/or the first connection region CNR1, and a second region S2 overlapping the second connection region CNR2. The pad structure PAD1 may extend in a direction parallel to the first direction D1 to at least partially overlap the cell array region CAR and/or the first connection region CNR1. After wire bonding, the first heat conductive pad PAD12 may be formed. As such, the positional relationship between the first heat conductive pad PAD12, the bonding wire WR, and the first via pad PAD11 in FIG. 17 may be identical to the positional relationship illustrated and described relative to FIG. 11, but for the first region S1 overlapping the cell array region CAR and/or the first connection region CNR1 in FIG. 17.

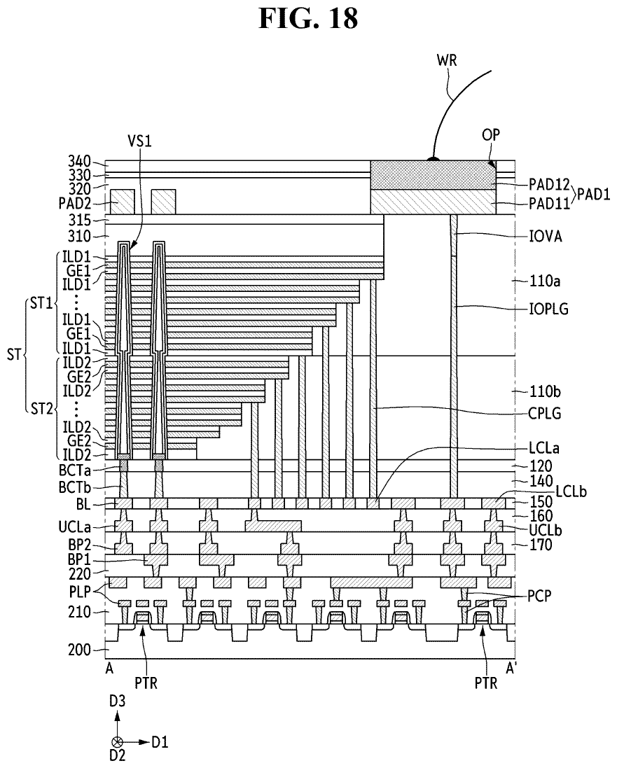

Referring to FIG. 18, after the first heat conductive pad PAD12 is formed, wire bonding may be performed. The pad structure PAD1 may extend in a direction parallel to the first direction D1 to at least partially overlap the cell array region CAR and/or the first connection region CNR1. The first heat conductive pad PAD12 may completely fill the first opening OP. As such, the positional relationship between the first heat conductive pad PAD12, the bonding wire WR, and the first via pad PAD11 in FIG. 18 may be identical to the positional relationship illustrated and described relative to FIG. 12, but for the first region S1 overlapping the cell array region CAR and/or the first connection region CNR1 in FIG. 18.

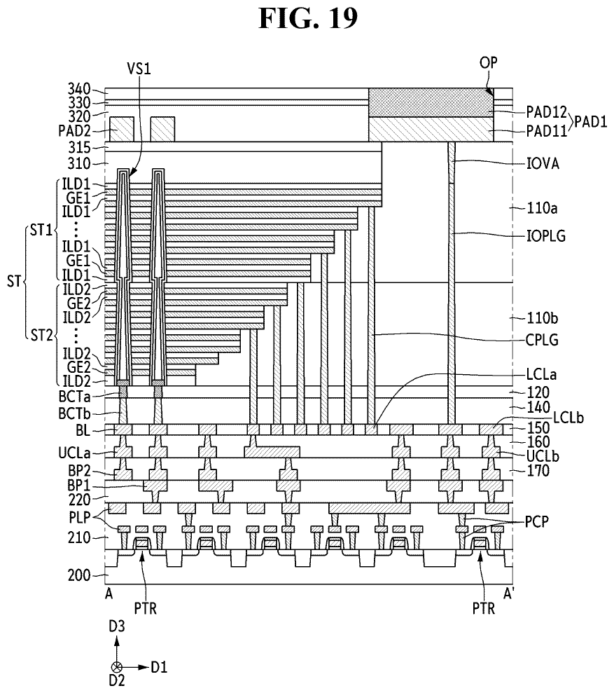

Referring to FIG. 19, the bonding wire WR may not be arranged on the pad structure PAD1. In this case, the pad structure PAD1 may not be connected via the bonding wire WR. The pad structure PAD1 may extend in the first direction D1 to at least partially overlap the cell array region CAR and/or the first connection region CNR1. The first heat conductive pad PAD12 may completely fill the first opening OP. As such, the positional relationship between the first heat conductive pad PAD12, the bonding wire WR, and the first via pad PAD11 in FIG. 19 may be identical to the positional relationship illustrated and described relative to FIG. 13, but for the first region S1 overlapping the cell array region CAR and/or the first connection region CNR1 in FIG. 19.

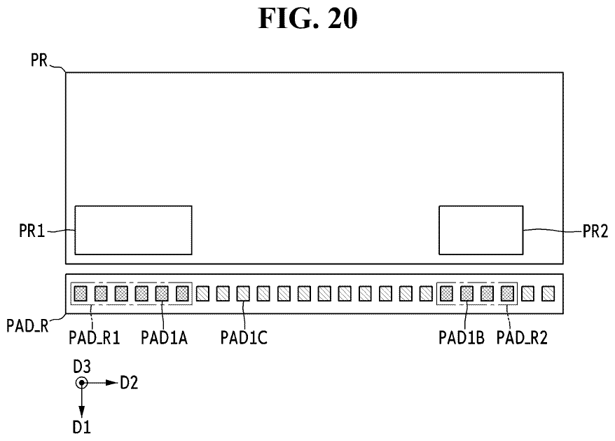

FIGS. 20 through 24 are plan views of the semiconductor device according to some embodiments of the present disclosure, illustrating the semiconductor package in FIG. 3 or 4 as viewed from above. For convenience, overlapping content with FIGS. 1 through 19 may be omitted.

Referring to FIGS. 20 through 24, a peripheral circuit PR may include a first peripheral circuit PR1 and a second peripheral circuit PR2, which are electrically connected to the cell structure CS in FIGS. 6 through 19. The peripheral circuit PR in FIGS. 20 through 24 may correspond to the peripheral circuit structure PS in FIGS. 6 through 19.

The peripheral circuit PR may be adjacent to a pad region PAD_R in the first direction D1. The pad region PAD_R may include a first pad region PAD_R1 where (1_1)-th pad structures PAD1A are positioned and a second pad region PAD_R2 where first pad structures PAD1B are positioned. The first and second pad regions PAD_R1 and PAD_R2 may be spaced apart in the second direction D2.

The pad structure PAD1 in FIGS. 6 through 19 may include the (1_1)-th pad structures PAD1A, the (1_2)-th pad structures PAD1B, and (1_3)-th pad structures PAD1C. The (1_1)-th pad structures PAD1A may be first primary pad structures, the (1_2)-th pad structures PAD1B may be second primary pad structures, and the (1_3)-th pad structures PAD1C may be third primary pad structures. From a planar perspective, the (1_1)-th pad structures PAD1A may be positioned adjacent to the first peripheral circuit PR1 in the first direction D1. The (1_2)-th pad structures PAD1B may be positioned adjacent to the second peripheral circuit PR2 in the first direction D1. The (1_3)-th pad structures PAD1C may be positioned adjacent to the entire peripheral circuit PR excluding the first and second peripheral circuits PR1 and PR2.

For example, the first peripheral circuit PR1 adjacent to the (1_1)-th pad structures PAD1A may be, but is not limited to, a voltage generation circuit, and the second peripheral circuit PR2 adjacent to the (1_2)-th pad structures PAD1B may be, but is not limited to, an input/output circuit. The peripheral circuit PR adjacent to the (1_3)-th pad structures PAD1C may be, but is not limited to, one of a decoder circuit or a page buffer.

The (1_1)-th pad structures PAD1A may each include a first via pad (“PAD11” in FIGS. 6 through 19) and a first heat conductive pad (“PAD12” in FIGS. 6 through 19) positioned within a first opening (“OP” in FIGS. 6 through 19) above the first via pad PAD11.

Although not explicitly illustrated, the (1_2)-th pad structures PAD1B may each include a second via pad (not illustrated) and a second heat conductive pad (not illustrated) positioned within a second opening (not illustrated) above the second via pad. The structure and shape of the second via pad, second opening, and second heat conductive pad may be similar to those of the first via pad PAD11, first opening OP, and first heat conductive pad PAD12 as described above with reference to FIGS. 6 through 19.

Referring to FIG. 20, the (1_3)-th pad structures PAD1C may each include a third via pad (not illustrated) but may not include a heat conductive pad. That is, only some of the pad structures in the pad region PAD_R may include heat conductive pads.

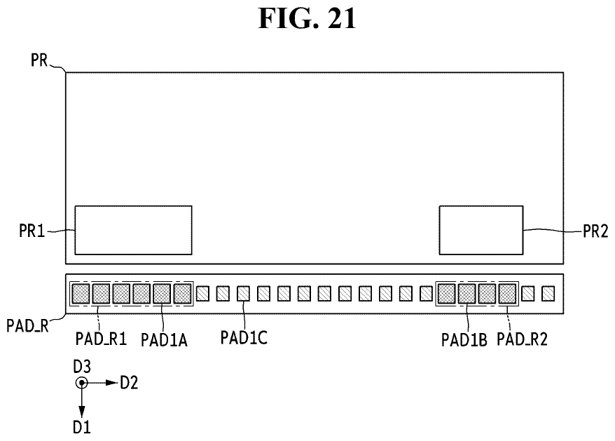

Referring to FIG. 21, the pad region PAD_R may include pad structures of different sizes. For example, the sizes of the (1_1)-th pad structures PAD1A and the (1_2)-th pad structures PAD1B may each be larger than the size of the (1_3)-th pad structures PAD1C, which do not include heat conductive pads. In this case, the (1_1)-th pad structures PAD1A and the (1_2)-th pad structures PAD1B may each extend in a direction parallel to the first direction D1 to at least partially overlap the cell array region CAR and/or the first connection region CNR1.

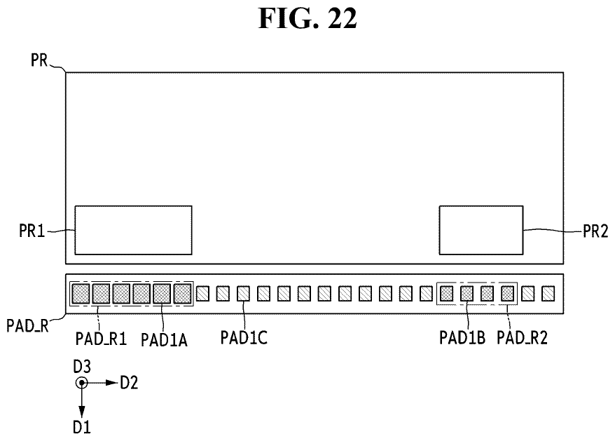

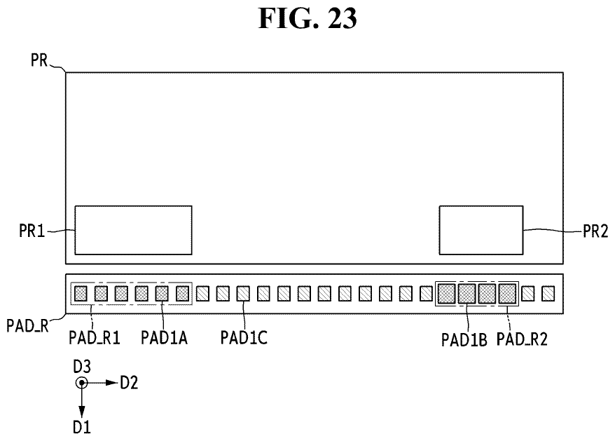

Referring to FIG. 22, the size of the (1_1)-th pad structures PAD1A may be larger than the size of the (1_2)-th pad structures PAD1B. Referring to FIG. 23, the size of the (1_2)-th pad structures PAD1B may be larger than the size of the (1_1)-th pad structures PAD1A.

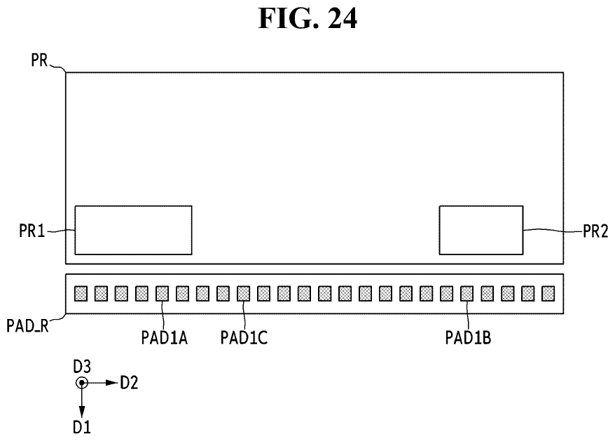

Referring to FIG. 24, the pad structures in the pad region PAD_R may all include heat conductive pads. The (1_3)-th pad structures PAD1C may each include a third via pad (not illustrated) and a third heat conductive pad (not illustrated) positioned within a third opening (not illustrated) above the third via pad. Additionally, the pad region PAD_R may include pad structures of the same size. The sizes of the (1_1)-th pad structures PAD1A, the (1_2)-th pad structures PAD1B, and the (1_3)-th pad structures PAD1C may be the same.

However, the number and spacing of the pad structures illustrated in FIGS. 20 through 24 are not particularly limited.

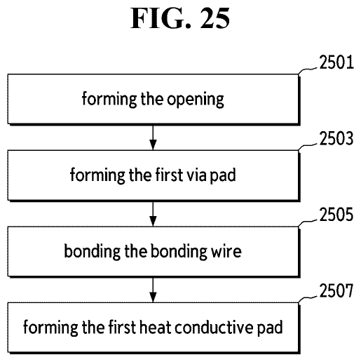

FIG. 25 is a flowchart illustrating a method of forming the semiconductor device according to some embodiments of the present disclosure, in particular, the semiconductor device illustrated and described relative to FIGS. 6 and 9-19. For example, at 2501, the method may comprise forming the opening OP in the insulating layer (e.g., the capping insulating film 320, the protective film 330, and the passivation layer 340). Formation of the opening OP may expose the insulating film 110a. In some embodiments, the opening OP may be formed by patterning, for example, with the patterning comprising applying a photoresist over the insulating layer, patterning the photoresist, etching the insulating layer, and/or removing the photoresist. The opening OP may be formed with the dimensions illustrated in FIGS. 6 and 9-13, or with the dimensions illustrated in FIGS. 14-19 (e.g., with the two regions S1, S2), for example. At 2503, the method may comprise forming the first via pad PAD11 in the opening OP. In some embodiments, the first via pad PAD11 may be formed by deposition (e.g., deposition of a barrier layer, a seed layer, etc.) and electroplating. At 2505, the method may comprise bonding the bonding wire WR to the pad structure PAD1. For example, the bonding wire WR may be bonded to the first via pad PAD11 (e.g., as illustrated in FIGS. 6, 11, 14, and 17), and the bonding may occur prior to the formation of the first heat conductive pad PAD12. The bonding of the bonding wire WR may occur by ball bonding, wedge bonding, etc. At 2507, the method may comprise forming the first heat conductive pad PAD12 over the first via pad PAD11. The first heat conductive pad PAD12 may be formed by deposition (e.g., deposition of a barrier layer, a seed layer, etc.) and electroplating, for example. At 2507, the first heat conductive pad PAD12 may be formed to partially, or completely, fill the opening OP. In some embodiments, when the bonding wire WR is bonded to the first via pad PAD11 (e.g., at 2505), the first heat conductive pad PAD12 may be formed over the deformed portion of the bonding wire WR that is connected to the first via pad PAD11. Alternatively, in some embodiments, step 2505 may not occur before the formation of the first heat conductive pad PAD12 (e.g., at 2507). Rather, step 2505 may occur after the formation of the first heat conductive pad PAD12 (e.g., at 2507). For example, after the first heat conductive pad PAD12 has been formed at 2507, the bonding wire WR may be bonded to the first heat conductive pad PAD12 (e.g., as illustrated in FIGS. 9, 12, 15, and 18). Alternatively, in some embodiments, step 2505 may not occur at all, such that the bonding wire WR may not be bonded to the pad structure PAD1 (e.g., as illustrated in FIGS. 10, 13, 16, and 19).

In some embodiments, heat conductive pads may be positioned on pads located near each circuit that generates significant heat, such as a voltage generation circuit and/or an input/output circuit. Furthermore, the size of heat conductive pads located closer to such circuit may be made larger than that of heat conductive pads located farther from such circuit. This can improve heat dissipation efficiency and enhance the reliability of the semiconductor device according to some embodiments of the present disclosure.

Although the embodiments of the present disclosure have been described with reference to the accompanying figures, the present disclosure is not limited to these embodiments and may be implemented in various other forms. Those skilled in the art to which the present disclosure pertains will understand that modifications can be made without departing from the spirit or essential characteristics of the present disclosure. Therefore, the embodiments described herein are illustrative in all respects and not restrictive.

What is claimed is:

1. A semiconductor device comprising:
a cell structure including a first region comprising memory cells and a second region located at an edge of the first region;
a peripheral circuit structure including a peripheral circuit electrically connected to the cell structure;
a through via extending in a vertical direction within the second region of the cell structure;
a first pad structure connected to the through via, in the second region; and
a second pad structure on the cell structure, in the first region,
wherein the first pad structure includes a via pad in contact with the through via and a heat conductive pad positioned within an opening, above the via pad.

2. The semiconductor device of claim 1, further comprising:
an insulating layer positioned on the cell structure,
wherein
the opening is bordered by sidewalls of the insulating layer, and the via pad is positioned at a bottom of the opening, and
the heat conductive pad is positioned on the via pad.

3. The semiconductor device of claim 1, further comprising:
a bonding wire connected to the first pad structure.

4. The semiconductor device of claim 3, wherein a portion of the bonding wire is connected to the via pad, and the portion of the bonding wire that is connected to the via pad is positioned between the via pad and the heat conductive pad.

5. The semiconductor device of claim 3, wherein the bonding wire does not contact an upper surface of the via pad.

6. The semiconductor device of claim 1, wherein the heat conductive pad partially fills the opening.

7. The semiconductor device of claim 1, wherein the heat conductive pad completely fills the opening.

8. The semiconductor device of claim 1, wherein the first pad structure includes a first region overlapping the first region of the cell structure and a second region overlapping the second region of the cell structure.

9. The semiconductor device of claim 1, wherein
the peripheral circuit includes a first peripheral circuit and a second peripheral circuit, each electrically connected to the cell structure, and
the first pad structure includes a first primary pad structure positioned adjacent to the first peripheral circuit and second primary pad structure positioned adjacent to the second peripheral circuit.

10. The semiconductor device of claim 9, wherein sizes of the first primary pad structure and the second primary pad structure are different.

11. A semiconductor device comprising:
a cell structure including memory cells;
a peripheral circuit structure including a peripheral circuit electrically connected to the cell structure;
a through via extending in a vertical direction within the cell structure and positioned on the peripheral circuit structure;
a pad structure connected to, and positioned on, the through via; and
a bonding wire connected to the pad structure,
wherein
the pad structure includes a via pad and a heat conductive pad positioned within an opening, wherein the heat conductive pad is positioned above the via pad, and
the via pad does not contact the bonding wire, while the heat conductive pad is connected to, and contacts, the bonding wire.

12. The semiconductor device of claim 11, further comprising:
an insulating layer positioned on the cell structure,
wherein the insulating layer includes a photosensitive material.

13. The semiconductor device of claim 12, wherein
the heat conductive pad partially fills the opening, and
with respect to the vertical direction, an upper surface of the heat conductive pad is positioned below an upper surface of the insulating layer.

14. The semiconductor device of claim 12, wherein
the heat conductive pad completely fills the opening, and
with respect to the vertical direction, an upper surface of the heat conductive pad is positioned at a same level as, or above, an upper surface of the insulating layer.

15. The semiconductor device of claim 11, wherein
the cell structure includes a first region where the memory cells are positioned and a second region where the through via is positioned, and
the pad structure extends in a horizontal direction to at least partially overlap the first region.

16. A semiconductor device comprising:
a cell structure including memory cells;
a peripheral circuit structure including a first peripheral circuit and a second peripheral circuit, each electrically connected to the cell structure;
a first pad structure positioned adjacent to the first peripheral circuit; and
a second pad structure positioned adjacent to the second peripheral circuit,
wherein
the first pad structure includes a first via pad and a first heat conductive pad positioned within a first opening, wherein the first heat conductive pad is positioned above the first via pad, and
a size of the first pad structure is larger than a size of the second pad structure.

17. The semiconductor device of claim 16, wherein the second pad structure includes a second via pad and a second heat conductive pad positioned within a second opening, wherein the second heat conductive pad is positioned above the second via pad.

18. The semiconductor device of claim 16, wherein
the cell structure includes a first region where the memory cells are positioned and a second region located at an edge of the first region, and
the first pad structure overlaps at least a portion of the first region.

19. The semiconductor device of claim 16, wherein
the first peripheral circuit is a voltage generation circuit, and
the second peripheral circuit is an input/output circuit.

20. The semiconductor device of claim 16, wherein
the first peripheral circuit is one of a voltage generation circuit and an input/output circuit, and
the second peripheral circuit is one of a decoder circuit and a page buffer circuit.
